(19) United States
(12) Patent Application Publication
(10) Pub. No.: US 2010/0052077 A1
(43) Pub. Date: Mar. 4, 2010

(54) HIGH-K METAL GATE STRUCTURE INCLUDING BUFFER LAYER

(75) Inventors: Peng-Fu Hsu, Hsinchu (TW); Hsin-Chun Ko, Taichung (TW); Kang-Cheng Lin, Yonghe City (TW); Kuo-Tai Huang, Hsinchu (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/422,378

(22) Filed: Apr. 13, 2009

Related U.S. Application Data
(60) Provisional application No. 61/092,327, filed on Aug. 27, 2008.

(51) Int. Cl. H01L 29/78; H01L 21/336

(52) U.S. Cl. 257/411; 438/761; 438/591; 257/E29.255; 257/E21.409

(57) ABSTRACT

A high-k metal gate structure including a buffer layer and method of fabrication of such, is provided. The buffer layer may interpose an interface oxide layer and a high-k gate dielectric layer. In one embodiment, the buffer layer includes aluminum oxide. The buffer layer and the high-k gate dielectric layer may be formed in-situ using an atomic layer deposition (ALD) process.

### PRIORITY DATA

This application claims priority to Provisional Application Ser. No. 61/092,327 filed on Aug. 27, 2008, entitled “HIGH-K METAL GATE STRUCTURE INCLUDING BUFFER LAYER”, the entire disclosure of which is incorporated herein by reference.

### BACKGROUND

The present disclosure relates generally an integrated circuit device and, more particularly, a metal gate structure and method of fabrication.

As technology nodes decrease, semiconductor fabrication processes have introduced the use of gate dielectric materials having a high dielectric constant (e.g., high-k dielectrics). The high-k dielectrics exhibit a higher dielectric constant than the traditionally used silicon dioxide; this allows for thicker dielectric layers to be used to obtain similar equivalent oxide thicknesses (EOTs). The processes also benefit from the introduction of metal gate structures providing a lower resistance than the traditional polysilicon gate structures.

The use of high-k gate dielectrics typically requires an interface layer, typically an interfacial oxide layer, to be formed on a substrate to improve the high-k dielectric quality. However, issues may result from a mismatch between the high-k dielectric and the interfacial oxide layer in the gate structure. This mismatch may result in locates stress which can impact device performance such as threshold voltages (Vt). For example, threshold voltages may vary between wide and narrow width devices.

Therefore, what is needed is an improved gate structure and method of fabrication.

### BRIEF DESCRIPTION OF THE DRAWINGS

FIG. 1 is a flowchart illustrating an embodiment of a method of forming a high-k dielectric metal gate structure.

FIG. 2 is a cross-sectional view of a semiconductor device including a high-k metal gate structure.

FIG. 3 is a flowchart illustrating an embodiment of fabricating a gate structure including a buffer layer.

FIGS. 4, 5a, 5b, 6a, 6b, 7a, 7b, 8a, and 8b are cross-sectional views of a semiconductor substrate during an atomic layer deposition (ALD) process corresponding to the steps of an embodiment of the method of FIG. 3.

FIG. 9 illustrates a legend that provides the corresponding cross-hatching for each element illustrated in FIGS. 4, 5a, 5b, 6a, 6b, 7a, 7b, 8a, and 8b.

### DETAILED DESCRIPTION

The present disclosure relates generally to forming an integrated circuit device and, more particularly, a high-k metal gate structure of a semiconductor device (e.g., a FET device of an integrated circuit). It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Furthermore, included are descriptions of a first layer or feature “on” or “overlying” (as well as similar descriptions) a second layer or feature. These terms include embodiments where the first and second layer are in direct contact and those where one or more layers or feature are interposing the first and second layer. Further still, the exemplary embodiments are for illustrative purposes and not intended to be limiting, for example, numerous configurations of high-k metal gate structures are known in the art, including layers which may or may not be distinctly described herein but would be readily recognizable by one skilled in the art. Further still, though described herein as providing methods and structures associated with high-k gate dielectric and metal electrode gate structures, numerous other semiconductor structures, including, for example, polysilicon gate electrodes, may benefit from the present disclosure.

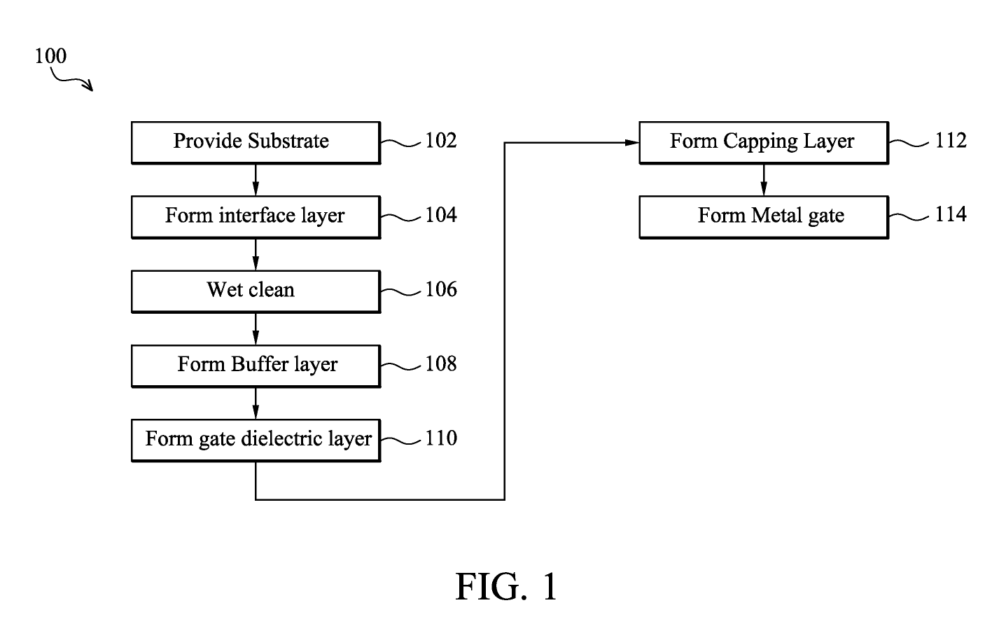

Referring to FIG. 1, illustrated is a flowchart providing an embodiment of a method 100 of forming a gate structure. The method 100 may be included during processing of an integrated circuit, or portion thereof, that may comprise static random access memory (SRAM) and/or other logic circuits, passive components such as resistors, capacitors, and inductors, and active components such as P-channel field effect transistors (PFET), N-channel FET (NFET), metal-oxide semiconductor field effect transistors (MOSFET), complementary metal-oxide semiconductor (CMOS) transistors, bipolar transistors, high voltage transistors, high frequency transistors, other memory cells, combinations thereof, and/or other semiconductor devices.

The method 100 begins at step 102 where a substrate (e.g., wafer) is provided. In an embodiment, the substrate includes a silicon substrate in crystalline structure. The substrate may include various doping configurations depending on design requirements as is known in the art (e.g., p-type substrate or n-type substrate) Other examples of the substrate include other elementary semiconductors such as germanium and diamond. Alternatively, the substrate may include a compound semiconductor such as, silicon carbide, gallium arsenide, indium arsenide, or indium phosphide. Further, the substrate may optionally include an epitaxial layer (epi layer), may be strained for performance enhancement, and/or may include a silicon-on-insulator (SOI) structure. Further still, the substrate may include a plurality of features formed thereon, including active regions, source and drain regions in the active regions, isolation regions (e.g., shallow trench isolation (STI) features), and/or other features known in the art.

The method 100 then proceeds to step 104 where an interface layer is formed on the substrate. The interface layer includes an oxide composition. The interface layer may include silicon, oxygen, and/or nitrogen. In an embodiment, the interface layer is SiO₂. The interface layer may include a thickness of approximately 5 to 10 angstroms, though various other thicknesses may be suitable. The interface layer may be formed by thermal oxidation, atomic layer deposition (ALD), and/or other suitable processes. The interface layer may be provided over an active region (e.g., over a region of the substrate where a gate may be formed).

The method 100 then proceeds to step 106 where a treatment of the interface layer is performed. The treatment may form an ALD-favorable surface of the interface layer. The step 106 may include a wet process such as, a wet clean. In an embodiment, a “standard clean” or SC1 (e.g., ammonia hydroxide-hydrogen peroxide-water solution) is used. In an embodiment of the method 100, step 106 is omitted from the method 100.

The method 100 then proceeds to step 108 where the buffer layer is formed. The buffer layer may be generated in-situ with the formation of a gate dielectric layer. The buffer layer may include an aluminum oxide composition.

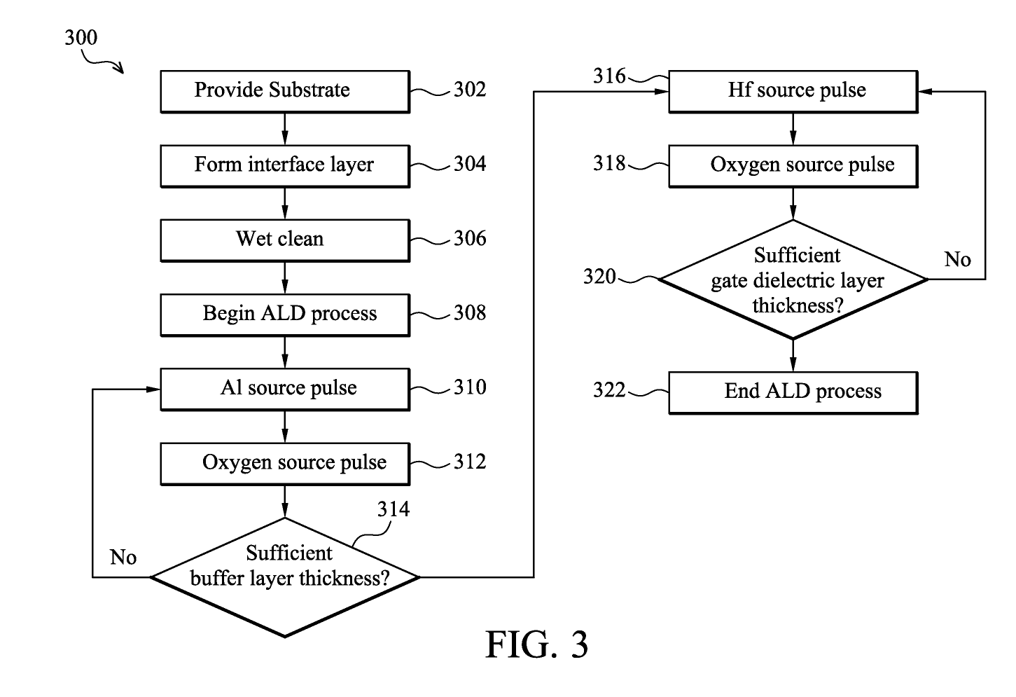

In one embodiment, the buffer layer has a thickness of approximately 2 angstroms or less, by way of example and not intended to be limiting. The buffer layer may be formed using the method of FIG. 3, or portion thereof. The buffer layer may reduce and/or eliminate the volume mismatch (e.g., local stress) between the interface layer, described above with reference to step 104, and an overlying layer such as, the gate dielectric layer, described below with reference to step 110. The buffer layer may mix with an underlying interface layer. This may reduce the equivalent oxide thickness (EOT) of the associated gate structure. In an embodiment, the buffer layer includes a “medium-k” dielectric material. The buffer layer may be provided (e.g., composition, thickness, etc) such that the mobility of the associated device (e.g., transistor) is not significantly degraded.

The method 100 then proceeds to step 110 where a gate dielectric layer is formed. The gate dielectric layer may include a high-k material (e.g., a material including a “high” dielectric constant, as compared to silicon oxide). Examples of high-k dielectrics include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), combinations thereof, and/or other suitable materials. The formation of the gate dielectric layer may include a plurality of layers including those used in forming an nMOS transistor gate structure and/or a pMOS transistor gate structure. The gate dielectric layer may be formed by ALD, chemical vapor deposition (CVD), and/or other suitable processes. In an embodiment, the thickness of the gate dielectric is between approximately 10 and 30 angstroms (A); this is exemplary only and not intended to be limiting.

The method 100 then continues to step 112 where a capping layer is formed on the substrate, for example, overlying the gate dielectric layer. The capping layer may include an oxide. The capping layer may include a work function dielectric for tuning a work function of a metal layer (e.g., providing the metal gate electrode). The capping layer may include aluminum or lanthanium based-dielectrics, and/or other suitable compositions. In an embodiment, the capping layer may be omitted, and/or other suitable layers may be included on the substrate to form a gate structure.

The method 100 then continues to step 114 where a metal gate (e.g., metal gate electrode) may be formed on the substrate. The metal gate may be formed using a “gate first” or a “gate last” process (e.g., including a sacrificial polysilicon gate). The metal gate may include one or more layers that when patterned form a metal gate electrode, or portion thereof. The metal gate may include one or more layers including Ti, TiN, TaN, Ta, TaC, TaSiN, W, WN, MoN, MoON, RuO₂, and/or other suitable materials. The metal gate may include one or more layers formed by physical vapor deposition (PVD), CVD, ALD, plating, and/or other suitable processes. In an embodiment, the metal gate includes a work function metal layer such that it provides an N-metal work function or P-metal work function of a metal gate. P-type work function materials include compositions such as ruthenium, palladium, platinum, cobalt, nickel, and conductive metal oxides, and/or other suitable materials. N-type metal materials include compositions such as hafnium, zirconium, titanium, tantalum, aluminum, metal carbides (e.g., hafnium carbide, zirconium carbide, titanium carbide, aluminum carbide), aluminides, and/or other suitable materials.

The method 100 may continue to provide additional layers in the gate structure, and/or form other features on the substrate such as, interconnects (lines and/or vias), contacts, and/or other features known in the art.

The method 100 may provide benefits over conventional processes including minimizing the local stress between a gate dielectric (e.g., high-k material) and an interface layer (e.g., oxide). The threshold voltage (Vt) variation observed between wide and narrow width devices may also be improved. In embodiment, the narrow width effect (NWE) is improved.

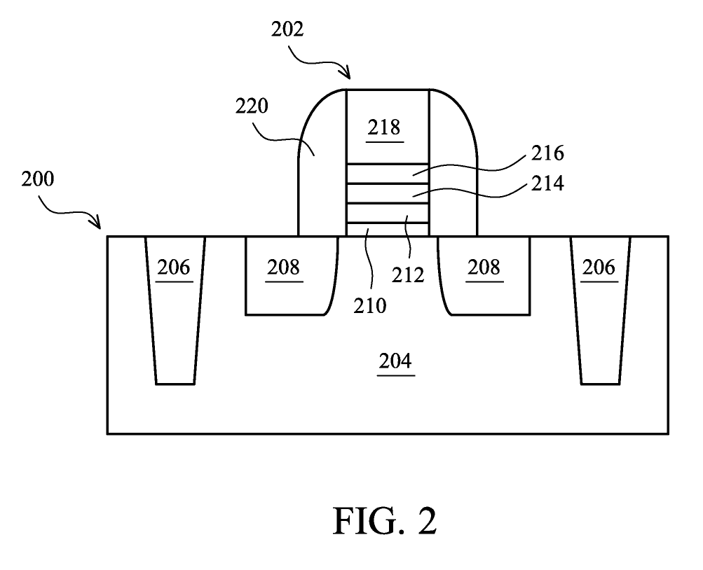

Referring now to FIG. 2, illustrated is a semiconductor device 200. The semiconductor device 200 may be formed using the method 100 and/or the method 300, described with reference to FIGS. 1 and 3 respectively. The semiconductor device includes a substrate 204, shallow trench isolation features 206, source/drain regions 208, spacers 220, and a gate structure 202. Though numerous other embodiments are possible. The gate structure 202 includes an interface layer 210, a buffer layer 212, a gate dielectric layer 214, a capping layer 216, and a metal gate electrode 218. However, numerous other configurations of the gate structure 202 are possible including omission of provided layers, and/or addition of one or more layers.

In an embodiment, the substrate 204 includes a silicon substrate (e.g., wafer) in crystalline structure. The substrate 204 may include various doping configurations depending on design requirements as is known in the art (e.g., p-type substrate or n-type substrate) Other examples of the substrate 204 include other elementary semiconductors such as germanium and diamond. Alternatively, the substrate 204 may include a compound semiconductor such as, silicon carbide, gallium arsenide, indium arsenide, or indium phosphide. Further, the substrate may optionally include an epitaxial layer (epi layer), may be strained for performance enhancement, and/or may include a silicon-on-insulator (SOI) structure.

The STI features 206 are formed in the substrate 204. The STI features 206 may include silicon oxide, silicon nitride, silicon oxynitride, fluoride-doped silicate glass (FSG), and/or a low-k dielectric material. Other isolation methods and/or features are possible in lieu of or in addition to STI. The STI features 206 may be formed using processes such as reactive ion etch (RIE) of the substrate 204 to form a trench which is filled with insulator material using deposition processes known in the art, followed by CMP processing. The STI features 206 may define an active region of the substrate 204 in which a nMOS or pMOS device may be formed.

The source/drain regions 208 may include lightly doped source/drain regions and/or heavy doped source/drain regions, and are disposed on the substrate 204 adjacent to (and associated with) the gate structure 202. The source/drain regions 208 may be formed by implanting p-type or n-type dopants or impurities into the substrate 204 depending on the desired transistor configuration. The source/drain features 208 may be formed by methods including photolithography, ion implantation, diffusion, and/or other suitable processes.

The spacers 220 are formed on both sidewalls of the gate structure 202. The spacers 220 may be formed of silicon oxide, silicon nitride, silicon oxynitride, silicon carbide, fluoride-doped silicate glass (FSG), a low-k dielectric material, combinations thereof, and/or other suitable material. The spacers 220 may have a multiple layer structure, for example, including one or more liner layers. The liner layers may include a dielectric material such as silicon oxide, silicon nitride, and/or other suitable materials. The spacers 220 may be formed by methods including deposition of suitable dielectric material and anisotropically etching the material to form the spacer 220 profile.

The gate structure 202 may be associated with an FET device such as, an nMOS or pMOS device. The interface layer 210 of the semiconductor substrate 202 may be substantially similar to the interface layer described above with reference to step 104 of the method 100 of FIG. 1. For example, the interface layer 210 may include an oxide (e.g., SiO₂). In an embodiment, the gate dielectric layer 214 includes a high-k dielectric material. The high-k dielectric material includes hafnium oxide (HfO₂). Other examples of high-k dielectrics include hafnium silicon oxide (HfSiO), hafnium silicon oxynitride (HfSiON), hafnium tantalum oxide (HfTaO), hafnium titanium oxide (HfTiO), hafnium zirconium oxide (HfZrO), combinations thereof, and/or other suitable materials. The high k-gate dielectric layer 214 may be formed by ALD, chemical vapor deposition (CVD), and/or other suitable processes.

The buffer layer 212 may be substantially similar to the buffer layer described above with reference to step 108 of the method 100 of FIG. 1. In an embodiment, the buffer layer includes aluminum oxide. In one embodiment, the buffer layer has a thickness of less than approximately 2 angstroms, by way of example and not intended to be limiting. The buffer layer may be formed using the method of FIG. 3, or portion thereof. The buffer layer may reduce and/or eliminate the volume mismatch (e.g., local stress) between the interface layer 210 and the gate dielectric layer 214.

The capping layer 216 may include a dielectric (e.g., an oxide). The capping layer 216 may be substantially similar to the capping layer described above with reference to step 112 of FIG. 1.

The metal layer 218 may form the metal gate electrode of the gate structure 202. The metal layer 218 may include one or more layers including Ti, TiN, TaN, Ta, TaC, TaSiN, W, WN, MoN, MoON, RuO₂, and/or other suitable materials. The metal layer 218 may include one or more layers formed by physical vapor deposition (PVD), CVD, ALD, plating, and/or other suitable processes. In an embodiment, the metal layer 218 includes a work function metal such that it provides an N-metal work function or P-metal work function of a metal gate. P-type work function materials include compositions such as ruthenium, palladium, platinum, cobalt, nickel, and conductive metal oxides, and/or other suitable materials. N-type metal materials include compositions such as hafnium, zirconium, titanium, tantalum, aluminum, metal carbides (e.g., hafnium carbide, zirconium carbide, titanium carbide, aluminum carbide), aluminides, and/or other suitable materials.

Thus, provided is the semiconductor device 200. The device 200 may provide benefits over conventional processes such as, to minimize the local stress between a gate dielectric (e.g., high-k material) and an interface layer (e.g., oxide). The threshold voltage (Vt) variation observed between wide and narrow width devices provided on the substrate 204, may also be improved. In embodiment, the narrow width effect (NWE) is improved.

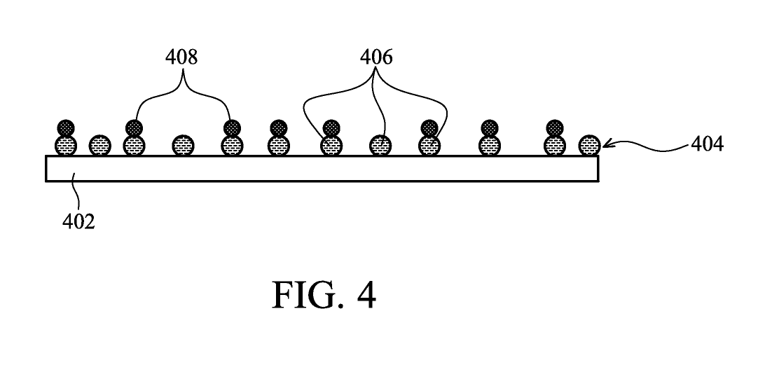

Referring now to FIG. 3, illustrated is a method of forming a gate structure including forming a buffer layer by ALD processing. FIGS. 4, 5a, 5b, 6a, 6b, 7a, 7b, 8a, and 8b provide example devices corresponding to one or more steps of the method 300. The method 300 begins at step 302 where a substrate is provided. The substrate may be substantially similar to the substrate 204, described above with reference to FIG. 2. The method 300 then proceeds to step 304 where an interface layer is formed on the substrate. The interface layer may be substantially similar to the interface layer 210, described above with reference to FIG. 2. Referring to the example of FIG. 4, the substrate 402 including an interface layer of silicon oxide is provided. The substrate 402 (including SiO₂ interface layer) includes surface 404 including oxygen 406 and hydrogen 408 (e.g., in a hydroxyl group).

The method 300 then proceeds to step 306 where a surface treatment process is performed. The surface treatment may be substantially similar to the treatment described above with reference to step 106 of the method 100 of FIG. 1. For example, the surface treatment may include a wet clean process such as, an SC1 clean. The surface treatment may introduce hydrogen such that a hydroxyl (OH) group is formed on the surface of the substrate, as illustrated by surface 404 of FIG. 4. This may ready the surface for subsequent ALD processing as described below. In an embodiment of the method 300, step 306 is omitted.

The method 300 then proceeds to step 308 where an atomic layer deposition (ALD) process begins. The ALD process, as described in the steps below, may form a buffer layer or a buffer layer and gate dielectric layer in-situ. An ALD process may include growing a film(s) (e.g., buffer or gate dielectric layer) by exposing a substrate (e.g., surface of a substrate) to alternating pulses (e.g., short introductions of vapor) of components, for example, a precursor (e.g., organometallic compound) and a co-reactant. The pulses may include self-limiting reactions and result in the deposition of a film and/or the chemisorbing of one or more components. Each pulse may be separated by an inert gas purge of an ALD tool chamber (e.g., the environment of the substrate 402).

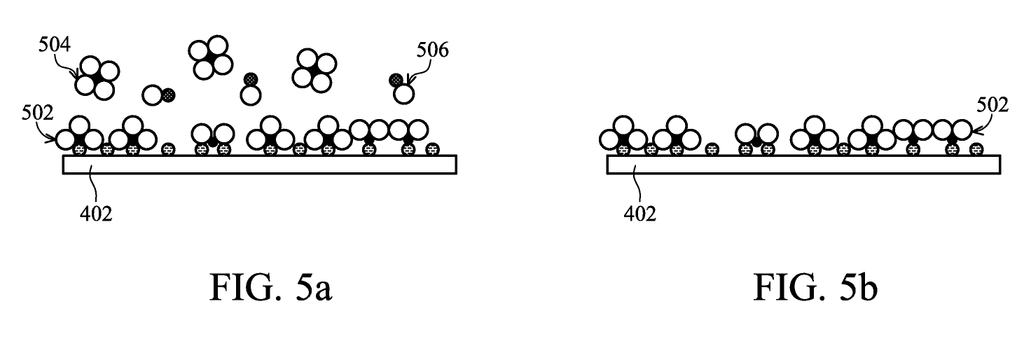

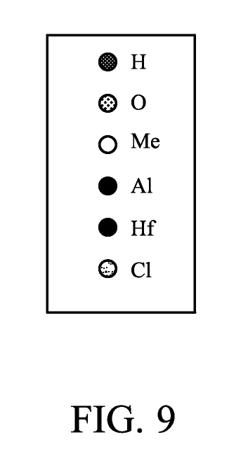

The method 300 then proceeds to step 310 where the ALD process includes a pulse providing a precursor including aluminum. In an embodiment, trimethyl aluminum (denoted AlMe₃, Al(CH₃)₃, or TMA) is pulsed into an ALD chamber where the substrate is exposed to the compound. The TMA may react with the hydroxyl groups present on the substrate surface. Referring to the example of FIG. 5a, AlCH₃)₃ 504 is provided to the environment of the substrate 402. A methane reaction product 506 may be produced, and purged from the environment of the substrate 402 (e.g., ALD chamber), as illustrated in FIG. 5b. Excess TMA 504 may also be purged. Therefore, a surface 502 is provided that includes silicon, oxygen, aluminum, and methane (e.g., Si—O—Al(CH₃)₂). It is noted that FIG. 9 illustrates a legend or key denoting the elements depicted in 5a, 5b and the remaining exemplary figures.

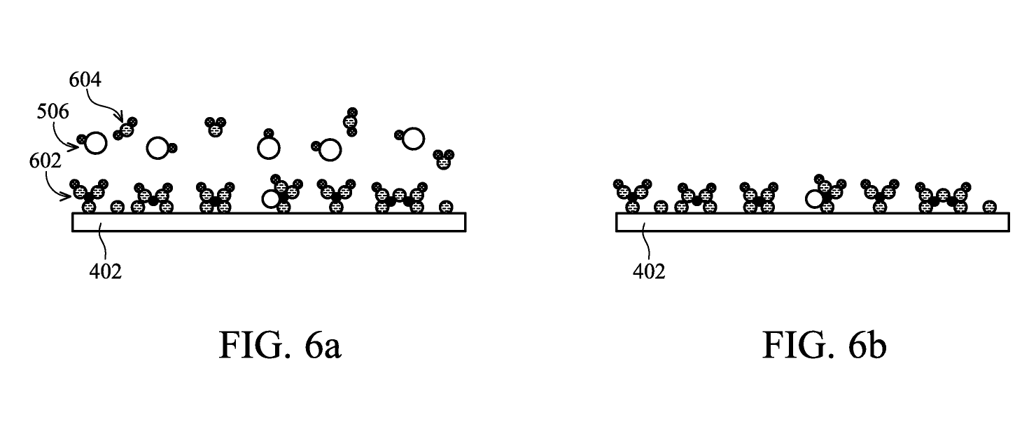

The method 300 then proceeds to step 312 where the ALD process includes a pulse providing a source of oxygen. In an embodiment, H₂O is pulsed into an ALD chamber where the substrate is exposed to the compound. The water vapor may react with the surface of the substrate. Referring to the example of FIG. 6a, H₂O 604 is introduced to the environment of the substrate 402. The H₂O 604 reacts with the surface (e.g., dangling methyl groups) forming the surface 602 including Al—O bonds. The H₂O 604 pulse may also provide the surface 602 including hydroxyl groups. A methane product 506 may be produced, and along with excess H₂O 604 may be purged from the environment of the substrate 402, as illustrated in FIG. 6b. Thus, steps 310 and 312 provide the formation of an atomic layer of a buffer film, as illustrated by the example of the surface 602 of FIG. 6b illustrating an atomic layer of aluminum oxide.

The method 300 then proceeds to step 314 where it determined if a sufficient thickness of the buffer layer has been formed. If it is insufficient, the method 300 returns to step 310 where a pulse including aluminum source is again provided. Additional cycles of providing an aluminum and oxygen source—steps 310 and 312—may be provided to form a sufficient buffer layer. The steps 310 and 312 provide one ALD cycle for providing a buffer layer, each cycle provides for an additional atomic layer. The steps 310 and 312 may be repeated, as illustrated by block 314, for any number of cycles to provide a desired thickness. In an embodiment, the cycles are continued to provide a buffer layer thickness of less than approximately 2 angstroms. In an embodiment, the cycles are continued to provide a buffer layer thickness of approximately 1.5 angstroms. In an embodiment, the buffer layer may be approximately 2.5-3 angstroms. As an example, 0.8 cycles may provide 1 angstrom of the buffer layer. In an embodiment, the step 314 determines the buffer layer is of sufficient thickness and the method 300 proceeds to step 316 including the formation of the gate dielectric layer. The gate dielectric layer may be formed in-situ (e.g., without transport of the substrate from the ALD chamber).

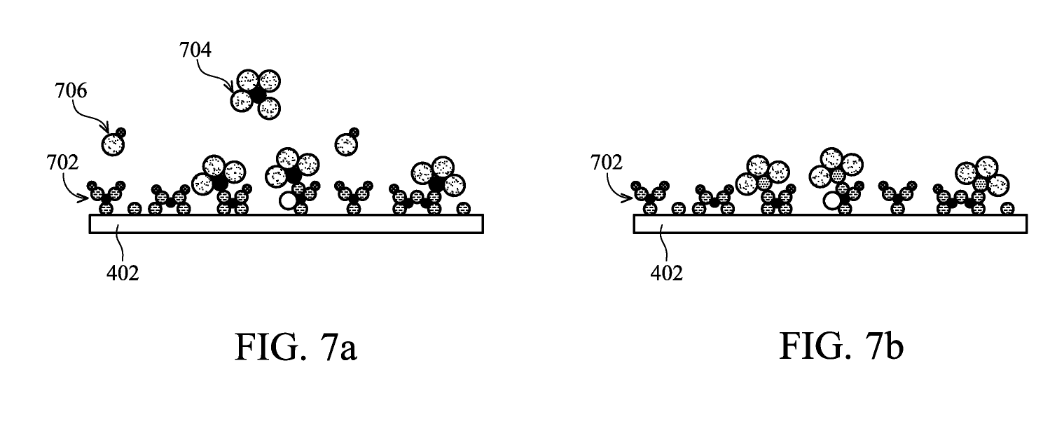

The method 300 (and the ALD process) then proceeds to step 316 where a pulse including hafnium source is provided to the substrate environment. In an embodiment, a HfCl₄ pulse is provided. Referring to the example of FIG. 7a, a HfCl₄ 704 pulse is provided to the substrate 402. Hf and Cl may react with the surface to form the surface 702. A purge may follow the HfCl₄ pulse. As illustrated by the FIGS. 7a and 7b, the purge may remove the unreacted HfCl₄ 704 and the reaction product HCl 706 from the environment of the substrate 402.

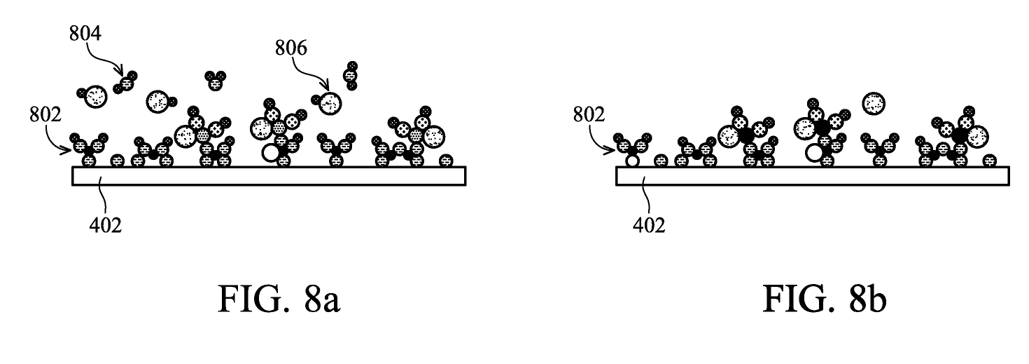

The method 300 and the ALD process then proceed to step 318 where a pulse including a source of oxygen is provided. In an embodiment an H₂O 804 pulse is provided. The water 804 vapor may provide a reaction product of HCl 806 which is purged from the environment as illustrated by FIG. 8b. The excess H₂O 804 may also be purged. Thus, a surface 802 is provided including hafnium, oxygen, and/or hydrogen. Therefore, steps 316 and 318 provide the formation of an atomic layer of gate dielectric (e.g., halfnium oxide).

The method 300 then continues to step 320 where it is determined if sufficient thickness of gate dielectric is formed. If it is found insufficient, the method 300 returns to step 318 and step 318 and 320 are repeated until a gate dielectric of a sufficient thickness is provided. Each cycle of steps 318 and 320 provide an additional atomic layer of gate dielectric. In an embodiment, the thickness of the gate dielectric layer may be between approximately 10 and 30 A. If the thickness is sufficient, the method 300 proceeds to step 322 where the ALD process is completed.

The method 300 thus provides for the in-situ formation of an aluminum oxide buffer layer and a hafnium oxide layer of a gate dielectric. In other embodiments, deposition of other high-k materials in lieu of or in addition to hafnium oxide may provided. Thus, the method 300 provides for deposition of a high-k gate dielectric with a pre-pulse of TMA to provide a buffer layer interposing the high-k gate dielectric and an underlying interface layer.

While the preceding description shows and describes one or more embodiments, it will be understood by those skilled in the art that various changes in form and detail may be made therein without departing from the spirit and scope of the present disclosure. Therefore, the claims should be interpreted in a broad manner, consistent with the present disclosure.

What is claimed is:

1. A method of fabricating a gate of a semiconductor device, comprising:
forming an interface oxide layer on a semiconductor substrate;
forming a buffer layer directly on the interface oxide layer; and
forming a high-k dielectric layer directly on the buffer layer.

2. The method of claim 1, wherein the forming the buffer layer and the forming the high-k dielectric layer are in-situ.

3. The method of claim 1, wherein the buffer layer is formed using an atomic layer deposition (ALD) process.

4. The method of claim 1, wherein the buffer layer includes aluminum oxide.

5. The method of claim 1, wherein the forming the interface oxide layer includes performing a wet cleaning process on the formed interface oxide layer.

6. A method comprising:
providing a semiconductor substrate;
forming an interfacial oxide layer on the substrate;
forming a buffer layer and a gate dielectric layer in-situ using an atomic layer deposition (ALD) process, wherein the ALD process includes:
providing a first pulse including an aluminum source;
providing a second pulse after the first pulse, the second pulse including an oxygen source;
providing a third pulse including a hafnium source; and
providing a fourth pulse, after the third pulse, the fourth pulse including an oxygen source.

7. The method of claim 6, further comprising:
forming a metal gate electrode on the high-k gate dielectric layer.

8. The method of claim 6, further comprising:
providing a fifth pulse after the second pulse and before the third pulse, the fifth pulse providing an aluminum source; and
providing a sixth pulse after the fifth pulse, the sixth pulse including an oxygen source.

9. The method of claim 6, wherein the first and second pulses provides the buffer layer wherein the buffer layer includes aluminum oxide.

10. The method of claim 6, wherein the third and fourth pulses form the gate dielectric layer, and wherein the gate dielectric layer is selected from the group consisting of hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), combinations thereof.

11. A method of claim 6, further comprising:
performing a surface treatment on the interfacial oxide layer prior to forming the buffer layer.

12. The method of claim 11, wherein the surface treatment includes a wet clean, and wherein the wet clean includes a standard clean 1 (SC1) solution.

13. The method of claim 6, wherein the first pulse, second pulse, third pulse, and fourth pulse occur in the same process chamber.

14. The method of claim 6, wherein each of the first pulse, second pulse, third pulse, and fourth pulse are followed by a purge process.

15. A semiconductor device, comprising:
a substrate;
an interface layer formed on the substrate;
a buffer layer formed on the interface layer; and
a gate dielectric layer formed on the buffer layer.

16. The device of claim 15, wherein the buffer layer includes aluminum oxide.

17. The device of claim 15, wherein the buffer layer is formed by atomic layer deposition in-situ with the gate dielectric layer.

18. The device of claim 15, wherein the gate dielectric layer includes a high-k material selected from the group consisting of: hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), and combinations thereof.

19. The device of claim 15, wherein the buffer layer includes a thickness of less than approximately 2 angstroms.

20. The device of claim 15, further comprising:
a metal gate electrode formed on the gate dielectric layer.
